(19) United States
(12) Patent Application Publication
(10) Pub. No.: US 2009/0014884 A1
(43) Pub. Date: Jan. 15, 2009

(54) SLOTS TO REDUCE ELECTROMIGRATION FAILURE IN BACK END OF LINE STRUCTURE

(75) Inventor: Baozhen Li, South Burlington, VT (US)

Correspondence Address: HOFFMAN WARNICK LLC, 75 STATE ST, 14TH FLOOR, ALBANY, NY, 12207, US

(73) Assignee: International Business Machines Corporation, Armonk, NY (US)

(21) Appl. No.: 11/775,914

(22) Filed: Jul. 11, 2007

(51) Int. Cl. H01L 23/52; H01L 21/4763

(52) U.S. Cl. 257/767; 438/637; 257/E21.495; 257/E21.476

(57) ABSTRACT

A back-end of the line (BEOL) structure and method are disclosed. In one embodiment the BEOL structure may include: a copper line in an ultra low-k dielectric, the copper line connected on one end to a cathode via and on another end to an anode via; and a plurality of slots extending laterally along a length of the copper line, the plurality of slots being non-continuous along the length of the copper line, and wherein the plurality of slots reduce electromigration failure in the BEOL structure by enabling copper extrusions to occur along the plurality of slots.

### BACKGROUND

1. Technical Field

The disclosure relates generally to integrated circuit (IC) chip fabrication, and more particularly, a back end of the line (BEOL) structure.

2. Background Art

Electromigration in BEOL structures induces atom drift in the direction of electron current flow, enabling a void at the cathode end and metal extrusion at the anode end. The metal extrusion causes dielectric breakdown, intra-level shorting, and crack propagation during the thermal cycle, therefore enabling major reliability concerns. For copper (Cu) interconnects, the dominant electromigration failure has been an increase in resistance due to copper depletion. During the electromigration process, the cathode end is under tensile stress due to Cu depletion and the anode end (or away from cathode end) is under a compressive stress due to Cu accumulation. Once the compressive stress exceeds the Cu adhesion strength threshold with a surrounding dielectric material, Cu may extrude out of the line and cause electrical shorts with neighboring lines.

### SUMMARY

A back-end of the line (BEOL) structure and method are disclosed. In one embodiment the BEOL structure may include: a copper line in a low-k dielectric, the copper line connected on one end to a cathode via and on another end to an anode via; and a plurality of slots extending laterally along a length of the copper line, the plurality of slots being non-continuous along the length of the copper line, and wherein the plurality of slots reduce electromigration failure in the BEOL structure by enabling copper extrusions to occur along the plurality of slots.

A first aspect of the disclosure is directed to a method of reducing electromigration failure in a back end of the line (BEOL) structure, the method comprising: forming a copper line in a low-k dielectric, the copper line connected at one end to a cathode via and at another end to an anode via; and forming a plurality of slots extending laterally along a length of the copper line, the plurality of slots being non-continuous along the length of the copper line, and wherein the plurality of slots reduce electromigration failure in the BEOL structure by enabling copper extrusions to occur along the plurality of slots.

A second aspect of the disclosure is directed to a back-end of the line (BEOL) structure comprising: a copper line in a low-k dielectric, the copper line connected at one end to a cathode via and at another end to an anode via; and a plurality of slots extending laterally along a length of the copper line, the plurality of slots being non-continuous along the length of the copper line, and wherein the plurality of slots reduce electromigration failure in the BEOL structure by enabling copper extrusions to occur along the plurality of slots.

The illustrative aspects of the present disclosure are designed to solve the problems herein described and/or other problems not discussed.

### BRIEF DESCRIPTION OF THE DRAWINGS

These and other features of this disclosure will be more readily understood from the following detailed description of the various aspects of the disclosure taken in conjunction with the accompanying drawings that depict various embodiments of the disclosure, in which:

FIG. 1 shows embodiments of a method and a structure according to the disclosure.

It is noted that the drawing of the disclosure is not to scale. The drawing is intended to depict only typical aspects of the disclosure, and therefore should not be considered as limiting the scope of the disclosure.

### DETAILED DESCRIPTION

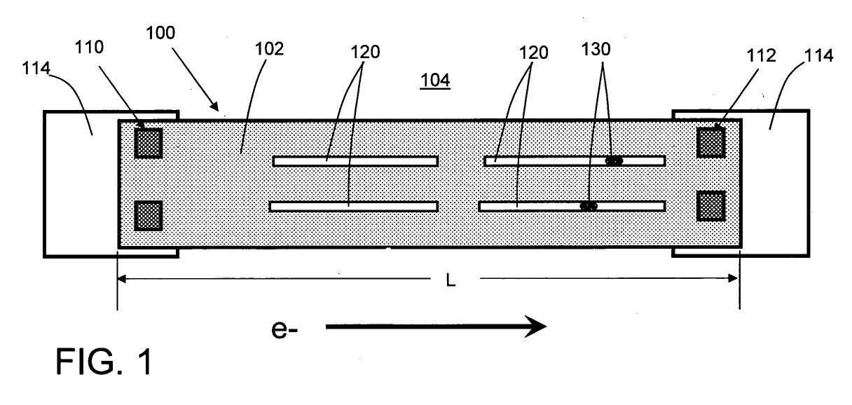

Turning to the drawing, FIG. 1 shows a back end of line (BEOL) structure 100 according to the disclosure. In one embodiment, BEOL structure 100 (hereinafter simply “structure 100”) includes a copper line 102 in a low-k dielectric 104. Low-k dielectric 104 may be any dielectric having a dielectric constant k of less than approximately 3.2. Illustrative low-k materials may include but are not limited to: octamethyleyclotetrasiloxane (OMCTS), hydrogenated silicon oxycarbide (SiCOH), porous SiCOH, boro-phosho-silicate glass (BPSG), silsesquioxanes, carbon (C) doped oxides (i.e., organosilicates) that include atoms of silicon (Si), carbon (C), oxygen (O), and/or hydrogen (H), thermosetting polyarylene ethers, SiLK (a polyarylene ether available from Dow Chemical Corporation) or layers thereof. Copper line 102 is connected at one end to a cathode via 110 and at another end to an anode via 112. Underlying layers 114 are also shown.

Structure 100 also includes a plurality of slots 120 extending laterally along a length (L) of copper line 102. In one embodiment, slots 120 are located closer to anode via 112 than to cathode via 110 since extrusions 130 are unlikely to occur near cathode via 110. Further, in one embodiment, slots 120 may be located approximately one Blech length away from cathode via 110. As used herein, “Blech length” is a lower limit for the length of a copper line 102 that will allow electromigration to occur. That is, any copper line 102 that has a length below the Blech length will not fail by electromigration because mechanical stress buildup causes a reversed migration process which reduces or even compensates the effective material flow towards the anode.

In one embodiment, slots 120 are non-continuous along the length of copper line 120. Recent observations by the inventor show that extrusions take place along the length of copper line 102, and copper extrudes out along a cap layer (not shown, over copper line 102) and copper interface to short with an adjacent line (not shown). For copper lines 102 within higher dielectric constant materials such as silicon oxide or dense SiCOH, the adhesion between cap/Cu layers is fairly strong. Consequently, resistance increase caused electromigration failures precede those caused by extrusions. With the new ultra low-k dielectric materials, however, the adhesion between the cap layer and copper is weaker, and extrusion caused electromigration failures start to precede resistance caused failures, especially for wider copper lines (e.g., lines >3 times of minimum width) with good via redundancy.

Strengthening the cap/Cu interface is one way to address this issue, but this approach comes with cost and process complexities. However, slots 120 reduce electromigration failure in structure 100 by enabling copper extrusions 130 (if any) to occur along the slots without extra cost and integration complexity. That is, slots 120 break the wider copper line 102 into pseudo-narrow lines to make extrusion(s) 130 less susceptible. If an extrusion 130 occurs, statistically, there is a good possibility that the extrusion takes place along slots 120. In this case, extrusion 130 is less harmful because the extruded copper will only short the copper separated by slots 120, and not cause circuit failures due to shorting with the neighboring copper lines. Slots 120 also allow for meeting any cheesing and current density requirements. Although slots 120 create a slight increase in current density, a certain degree of current density increase in copper line 102 away from the via/line contact will have minimal impact on the electromigration performance. Slots 120 can be provided through design service to insert long narrow slots to wider copper lines 102. The process may be implemented similar to a metal cheesing algorithm.

In another embodiment of the disclosure, a method of reducing electromigration failure in a BEOL structure 100 is included. One embodiment of the method may include forming copper line 102 in a low-k dielectric 104 with copper line 102 connected at one end to cathode via 110 and at another end to anode via 112. Plurality of slots 120 are also formed extending laterally along length L of copper line 102. Copper line 102 and slots 120 may be formed using any now known or later developed integrated circuit (IC) chip fabrication process, e.g., dielectric deposition, photolithography, etching, copper deposition and planarization.

The structures and methods described above are used in the fabrication and/or operation of integrated circuit (IC) chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multi-chip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The foregoing description of various aspects of the disclosure has been presented for purposes of illustration and description. It is not intended to be exhaustive or to limit the disclosure to the precise form disclosed, and obviously, many modifications and variations are possible. Such modifications and variations that may be apparent to a person skilled in the art are intended to be included within the scope of the disclosure as defined by the accompanying claims.

What is claimed is:

1. A method of reducing electromigration failure in a back end of the line (BEOL) structure, the method comprising:
forming a copper line in a low-k dielectric, the copper line connected at one end to a cathode via and at another end to an anode via; and
forming a plurality of slots extending laterally along a length of the copper line, the plurality of slots being non-continuous along the length of the copper line, and wherein the plurality of slots reduce electromigration failure in the BEOL structure by enabling copper extrusions to occur along the plurality of slots.

2. The method of claim 1, wherein the plurality of slots are located closer to the anode via than to the cathode via.

3. The method of claim 2, wherein the plurality of slots are located approximately one Blech length away from the cathode via.

4. A back-end of the line (BEOL) structure comprising:
a copper line in a low-k dielectric, the copper line connected at one end to a cathode via and at another end to an anode via; and
a plurality of slots extending laterally along a length of the copper line, the plurality of slots being non-continuous along the length of the copper line, and wherein the plurality of slots reduce electromigration failure in the BEOL structure by enabling copper extrusions to occur along the plurality of slots.

5. The structure of claim 4, wherein the plurality of slots are located closer to the anode via than to the cathode via.

6. The structure of claim 5, wherein the plurality of slots are located approximately one Blech length away from the cathode via.
